(19) United States
(12) Patent Application Publication
(10) Pub. No.: US 2009/0244798 A1
(43) Pub. Date: Oct. 1, 2009

(54) POWER STATUS NOTIFICATION METHOD AND POWER STATUS NOTIFICATION CIRCUIT

(75) Inventors: Yoshinari OGURA, Kawasaki (JP); Chongsuwanapaisal Pornchai, Kawasaki (JP); Yasushi Mizutani, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 12/392,714

(22) Filed: Feb. 25, 2009

(30) Foreign Application Priority Data
Mar. 31, 2008 (JP) 2008-90244

(51) Int. Cl. H02H 3/24; G01R 17/02; G01R 31/40

(52) U.S. Cl. 361/92; 327/72

(57) ABSTRACT

A power status notification method notifying a first device that a second power supply of a second device different from a first power supply of the first device is turned off, where a source voltage of the first power supply is different from a source voltage of the second power supply. The power status notification method and circuit include supplying the first device with a low-level notification signal indicating a power off state of the second power supply in a case where the source voltage of the second power supply drops to a predetermined voltage or is less than the predetermined voltage and setting the predetermined voltage at a value higher than a threshold level at which a circuit of the first device supplied with the notification signal recognizes as a low level.

### CROSS-REFERENCE TO RELATED APPLICATIONS

This application claims the benefit of Application No. 2008-90244, filed in the Japanese Patent Office on Mar. 31, 2008, the entire contents of which are incorporated herein by reference.

### BACKGROUND

1. Field

The present invention relates to a power status notification method and a power status notification circuit, and in particular to a power status notification method and a power status notification circuit according to which one of at least two circuits operating on different power supplies notifies a power status thereof to another circuit.

2. Description of the Related Art

In devices, such as boards, each having mounted thereon an LSI (large scale integrated circuit) or the like and operating on different power supplies, if one of the boards is turned off, the other board is notified. This notification is made to prevent the LSI or similar element on the board that has power turned off from being damaged by what is generally referred to the latch-up phenomenon. Generally, one board is notified of the status of the power supply of the other board with a signal called the “power ready” signal.

FIG. 1 is a circuit diagram showing an example of a conventional power status notification circuit. In FIG. 1, a board 1 operating on a first power supply and a board 2 operating on a second power supply are connected to each other through an interface 3. A source voltage VA of the first power supply is different from a source voltage VB of the second power supply. In the description that follows, VA designates both the first power supply and the source voltage thereof, and VB designates both the second power supply and the source voltage thereof. A control circuit 11, a driver 12, etc. are mounted on the board 1. A power status notification circuit 21, a receiver 22, etc. are mounted on the board 2. By way of explanation, assume that the driver 12 of the board 1 supplies a drive signal IF_AB to the receiver 22 of the board 2.

Whenever the second power supply VB is turned off, the power status notification circuit 21 supplies the control circuit 11 of the board 1 with a power ready signal PRDY_B_A of a low level notifying that the second power supply VB is turned off. The control circuit 11, whenever supplied with the power ready signal PRDY_B_A notifying that the second power supply VB is turned off, suppresses the output of the driver 12. As long as the second power supply VB is off, therefore, the receiver 22 on the board 2 is prevented from being driven by a high-level drive signal IF_AB supplied from the driver 12 of the board 1, thereby protecting the receiver 22 from the damage by the latch-up phenomenon.

FIG. 2 is a circuit diagram showing a power status notification circuit using a resistor. In FIG. 2, the same component parts as those in FIG. 1 are designated by the same reference numerals, respectively, and not described again. In FIG. 2, plural AND circuits 11-1 to 11-N and N drivers 12-1 to 12-N are mounted on the board 1, where N is a natural number of 2 or more. The input signals of the drivers 12-1 to 12-N are input through the AND circuits 11-1 to 11-N, respectively, when supplied with the power ready signal PRDY_B_A from the power status notification circuit 21 on the board 2. The board 2, on the other hand, has mounted thereon the power status notification circuit 21 having a pull-up resistor R and N receivers 22-1 to 22-N. Characters IF_AB#1 to IF_AB#N designate drive signals supplied to the receivers 22-1 to 22-N of the board 2 corresponding to the drivers 12-1 to 12-N of the board 1, respectively.

The low-level potential of the power ready signal PRDY_B_A output from the power status notification circuit 21 when the second power supply VB on the board 2 is turned off is ideally required to drop to almost 0 V. In the power status notification circuit 21 using the pull-up resistor R, however, the sneak current from the signal lines of the interface 3 may allow the power ready signal PRDY_B_A to drop to only near about the middle point of the source voltage VB, especially in the case where N is a large value. In the case of FIG. 2, for example, the boards 1 and 2 are connected with a certain resistance value through the drivers 12-1 to 12-N and the receivers 22-1 to 22-N. Even with the second power supply VB turned off, therefore, the source voltage VB is undesirably increased due to the sneak current from the first power supply VA. This sneak current increases in proportion to the number of the signal lines N of the interface 3. The source voltage VB, if assumed to increase by about 200 mV due to the sneak current when N is 32, for example, increases by a maximum of about 800 mV when N is 128. The source voltage VB, if increased by about 800 mV, reaches the neighborhood of the threshold level at which the control circuit 11 (the AND circuits 11-1 to 11-N) supplied with the power ready signal PRDY_B_A recognizes a high-level signal, and thus the control circuit 11 may erroneously recognize the low-level power ready signal PRDY_B_A as a high-level signal.

FIG. 3 is a circuit diagram showing a power status notification circuit using shunt resistors. Generally, the shunt resistor is a precision resistor high in accuracy and small in resistance and used for the purpose of current measurement. In FIG. 3, the same component parts as those in FIG. 2 are designated by the same reference numerals, respectively, and not described again. In FIG. 3, the power status notification circuit 21 includes a resistor R and plural shunt resistors 210 connected in parallel. Each shunt resistor 210 is connected between the second power supply VB and the ground to suppress the sneak current from the signal lines of the interface 3. In order to suppress the sneak current from the signal lines of the interface 3 and thereby sufficiently prevent the increase of the source voltage VB when the power supply VB is turned off, a great number of shunt resistors 210 having a comparatively low resistance value of, say, 30Ω are required. The provision of a great number of the shunt resistors 210, however, would cause the shunt resistors 210 to occupy a comparatively large mounting area on the board 2 on the one hand and would increase the current flowing steadily in the board 2 on the other hand.

A data output device for receiving power from a power supply and outputting a signal permitting a host computer to output image data is proposed in, for example, Japanese Patent Application Laid-Open No. 1-257080. Also, a circuit for generating a power-on reset signal is disclosed in, for example, Japanese PCT National Publication No. 2002-510890.

In light of the above and the other problems, there is a need for a power status notification method and system.

### SUMMARY

According to an embodiment, a power status notification method notifies a first device that a second power supply of a second device different from a first power supply of the first device is turned off, where a source voltage of the first power supply is different from a source voltage of the second power supply.

The circuit and method include supplying the first device with a low-level notification signal indicating an off state of the second power supply in a case where the source voltage of the second power supply drops to a predetermined voltage or is less than the predetermined voltage and setting the predetermined voltage at a value higher than a threshold level at which a circuit of the first device supplied with the notification signal recognizes as a low level.

Additional aspects and/or advantages will be set forth in part in the description which follows and, in part, will be apparent from the description, or may be learned by practice of the invention.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 is a circuit diagram showing an example of a conventional power status notification circuit;

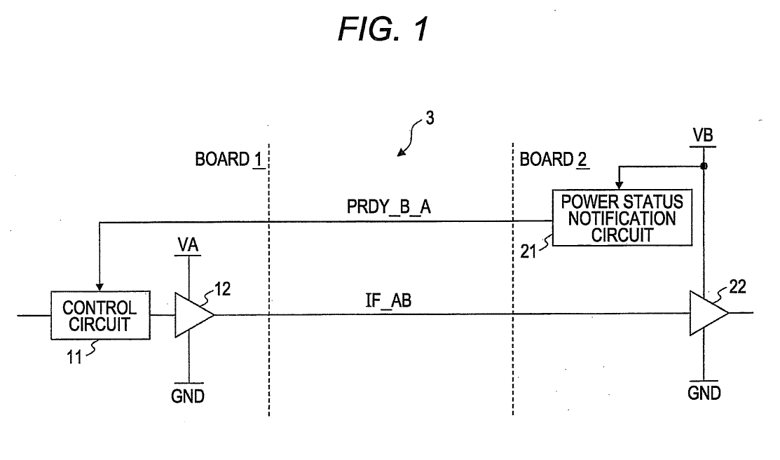

FIG. 2 is a circuit diagram showing a power status notification circuit using a resistor;

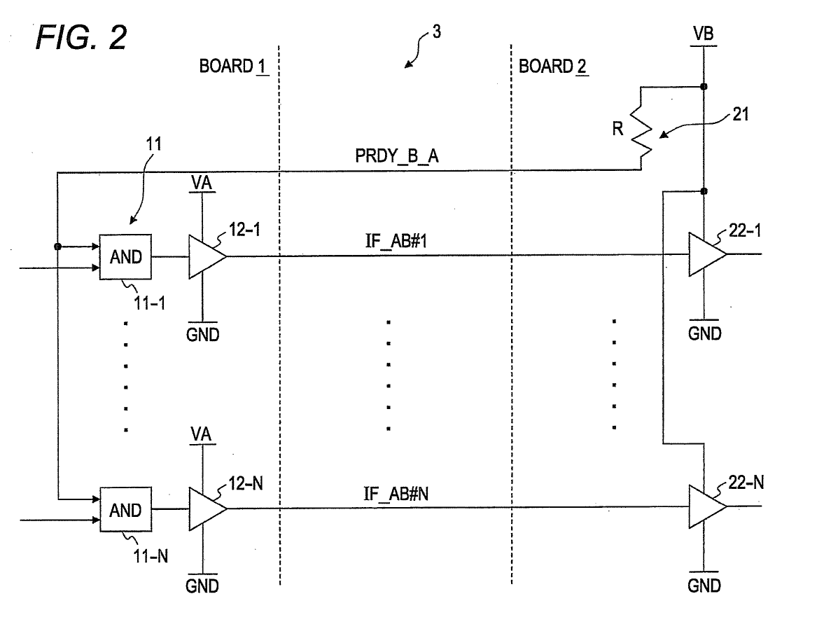

FIG. 3 is a circuit diagram showing a power status notification circuit using shunt resistors;

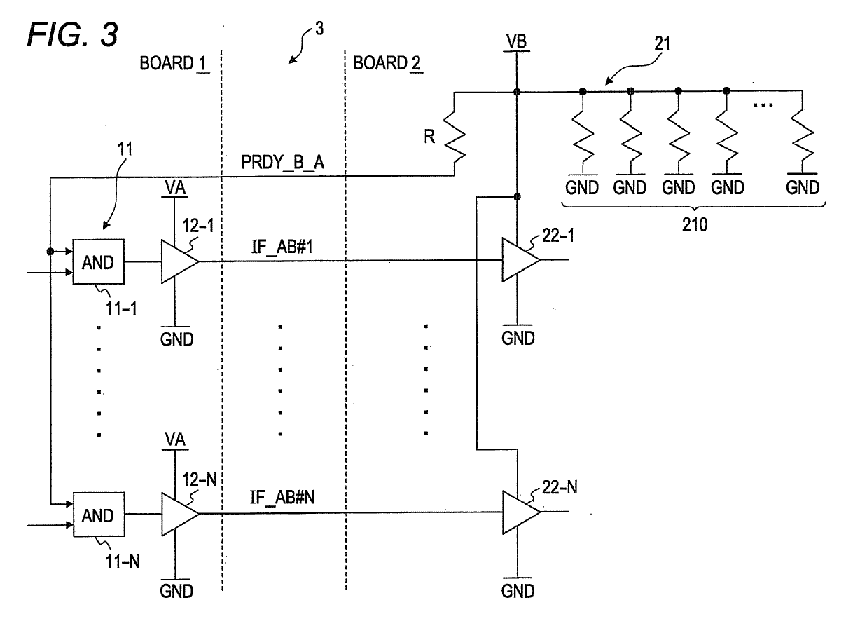

FIG. 4 is a circuit diagram showing an embodiment;

FIG. 5 is a circuit diagram showing a reset circuit;

FIG. 6 is a waveform diagram explaining an operation of a reset circuit;

FIG. 7 is a diagram explaining an operating condition of a reset circuit; and

FIG. 8 is a circuit diagram showing an embodiment.

### DETAILED DESCRIPTION OF EMBODIMENTS

Reference will now be made in detail to the embodiments, examples of which are illustrated in the accompanying drawings, wherein like reference numerals refer to the like elements throughout. The embodiments are described below to explain the present invention by referring to the figures.

In the power status notification method and the power status notification circuit disclosed by this invention, a first device having mounted thereon a circuit using a first power supply and a second device having mounted thereon a circuit using a second power supply different from the first power supply are connected to each other through a third device. The drive signal from the circuit mounted on the first device is supplied to the circuit of the second device through the third device. In the case where the second source voltage drops to a predetermined level or is lower than the predetermined level, the power status notification circuit supplies the first device with a low-level notification signal indicating that the second power supply is turned off. This predetermined voltage is set at a value higher than a threshold level at which the circuit of the first device supplied with the notification signal recognizes as a low level. The circuit of the first device suppresses the output of the high-level drive signal in response to the low-level notification signal.

The power status notification circuit may be mounted on either the first device or the third device. Further, although description of two circuits may be provided herein, the present invention is not limited to any particular number of circuits.

The configuration of the power status notification circuit is such that the sneak current can be suppressed without requiring additional mounting area on the first or third device, as the case may be. As explained in detail below, since a level at which a notification is provided can be set, for example, at a higher value than a threshold level, the notification can be provided including in association with circuits that do not allow power to drop all the way to 0V.

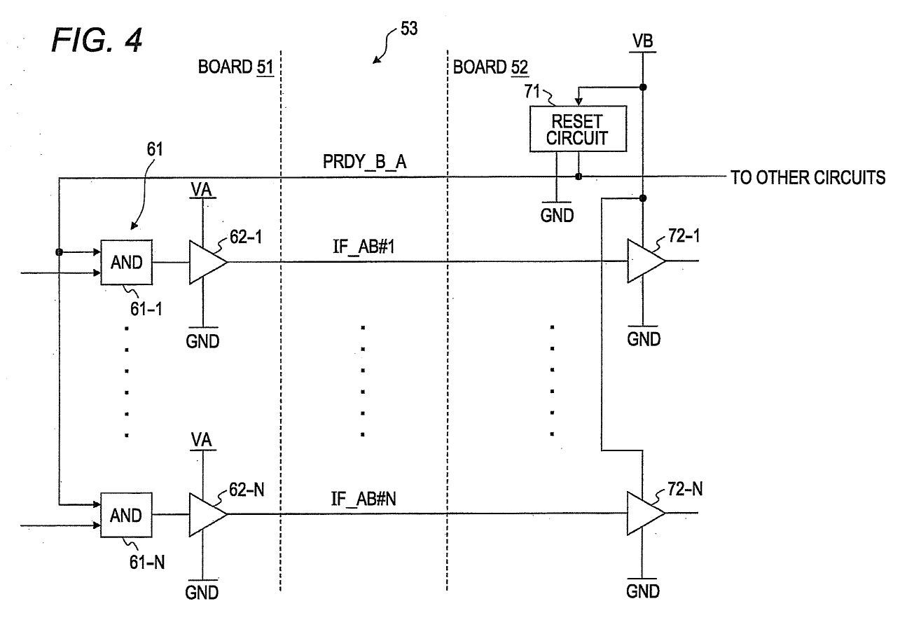

FIG. 4 is a circuit diagram showing an embodiment as an example of embodying the invention. In FIG. 4, a board 51 operated by a first power supply and a board 52 operated by the second power supply are connected with each other by an interface 53. The source voltage VA of the first power supply is different from the source voltage VB of the second power supply. In the description that follows, VA designates both the first power supply and the source voltage thereof, and VB designates both the second power supply and the source voltage thereof. The board 51 has mounted thereon a control circuit 61, drivers 62-1 to 62-N, etc. The control circuit 61 has AND circuits 61-1 to 61-N, where N is a natural number of 2 or more. The board 52, on the other hand, has mounted thereon a reset circuit 71, receivers 72-1 to 72-N, etc. The input signal to each of the drivers 62-1 to 62-N is input through the AND circuits 61-1 to 61-N supplied with the power ready signal PRDY_B_A from the reset circuit 71 of the board 52. By way of explanation, assume that the drivers 62-1 to 62-N of the board 51 supply the drive signals IF_AB#1 to IF_AB#N to the corresponding receivers 72-1 to 72-N, respectively, of the board 52.

As shown in FIG. 4, the reset circuit 71 functions as a power status notification circuit for example, and with the decrease of the source voltage VB to a predetermined voltage level or lower, outputs the low-level power ready signal PRDY_B_A as a notification signal. This predetermined voltage level is set at a value higher than a threshold level at which the circuits on the board 51 supplied with the power ready signal PRDY_B_A, i.e. the AND circuits 61-1 to 61-N in this case recognize as a low level. The AND circuits 61-1 to 61-N, once supplied with the low-level power ready signal PRDY_B_A by the reset circuit 71, suppress the output of the high-level drive signals IF_AB#1 to IF_AB#N of the drivers 62-1 to 62-N, and therefore, the receivers 72-1 to 72-N on the board 52 are not supplied with the high-level drive signals IF_AB#1 to IF_AB#N.

Incidentally, the power ready signal PRDY_B_A output from the reset circuit 71 can be used for initialization of, for example, other LSIs (not shown) mounted on the board 52. Thus, the invention not only provides a notification of a power status but also enables resetting that indicates when a device power supply has dropped to or is below a predetermined level.

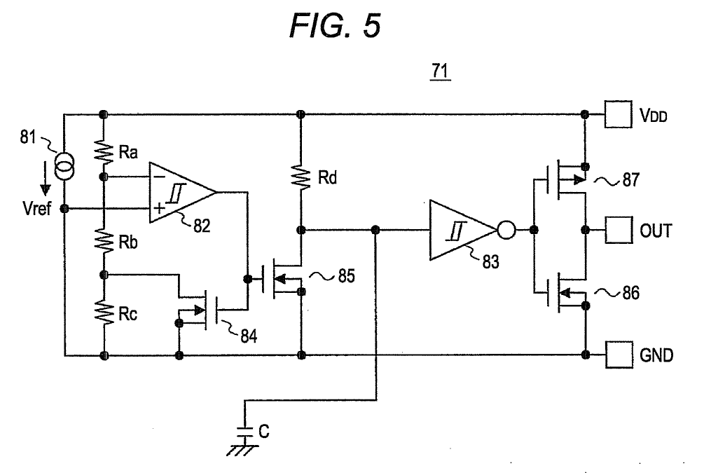

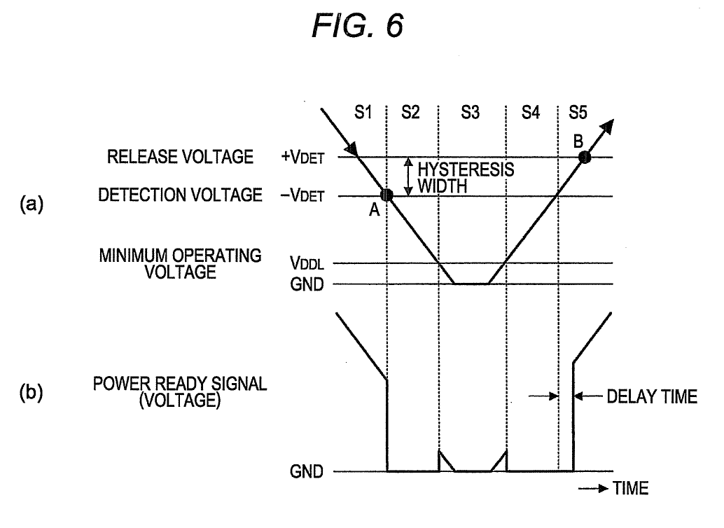

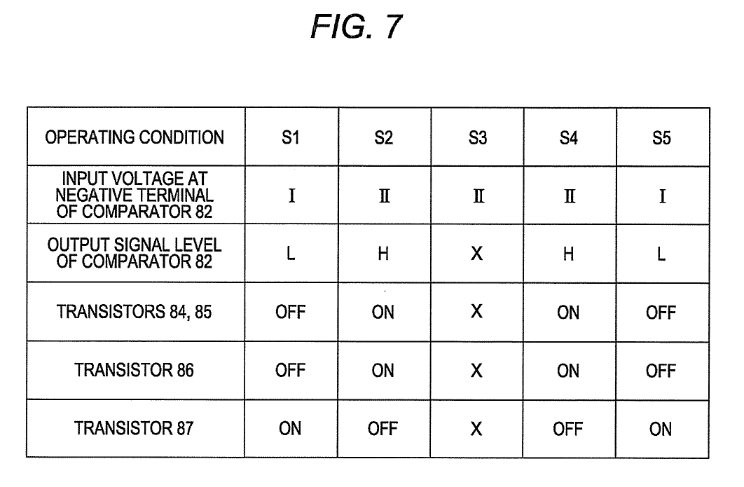

FIG. 5 is a circuit diagram showing the reset circuit 71. FIG. 6 is a waveform diagram for explaining an operation of the reset circuit 71, and FIG. 7 is a diagram for explaining an operating condition of the reset circuit 71.

The reset circuit 71 includes a current source 81, a comparator 82, a Schmitt trigger circuit 83, N-channel transistors 84 to 86, a P-channel transistor 87, resistors Ra, Rb, Rc, Rd and a capacitor C connected as shown in FIG. 5. VDD designates a power terminal, GND a grounding terminal, and OUT an output terminal. The capacitor C may be externally connected or omitted. Generally, the Schmitt trigger circuit 83 represents a waveform shaping circuit having a hysteresis characteristic.

In FIGS. 6 and 7, S1 to S5 show an operating condition of the reset circuit 71. In FIG. 6, (a) shows a source voltage (VB in FIG. 4) supplied to the power terminal VDD, and (b) the power ready signal (PRDY_B_A in FIG. 4) output from the output terminal OUT. Also, FIG. 7 shows the input voltage at the inverted input negative terminal of the comparator 82, the output signal level of the comparator 82, the on/off state of the transistors 84, 85 and the on/off state of the output transistors 86, 87. In FIG. 7, reference numeral I designates an input voltage expressed as {(Rb+Rc)/(Ra+Rb+Rc)}×VDD, numeral II an input voltage expressed as {Rb/(Ra+Rb)}×VDD, character L as a low level, character H as a high level, character OFF as an off state, the character ON as an on state and “unknown” as indicative that the voltage is unknown the is “X” unknown voltage.

In the operating status S1, the power ready signal output from the output terminal OUT is equal to the source voltage VDD (pull-up voltage in the case where an N-channel open-drain transistor is used in the output stage).

In the operating status S2, on the other hand, assuming that the source voltage VDD drops to the detection voltage −V_{DET} at point A, the reference voltage V_{ref} input to the non-inverted positive input terminal of the comparator 82 satisfies the relation V_{ref}≧VDD×{(Rb+Rc)/(Ra+Rb+Rc)}, the output signal of the comparator 82 turns high (H) from low level (L), and the power ready signal becomes equal to GND.

In the operating status S3, assuming that the source voltage VDD is lower than the minimum operating voltage V_{DDL}, the operation of the transistors 86, 87 in the output voltage becomes unknown (the pull-up voltage is output as a power ready signal in the case where the N-channel open-drain transistor is used in the output stage).

In the operating status S4, the power ready signal becomes equal to GND.

In the operating status S5, assuming that the source voltage VDD rises beyond the release voltage +V_{DET} at point B, the reference voltage V_{ref} satisfies the relation V_{ref}≦VDD×{Rb/(Ra+Rb)}, the output signal of the comparator 82 reaches the threshold voltage at which the high signal level is recognized, the output signal of the Schmitt trigger circuit 83 is inverted from high to low level, and the power ready signal becomes equal to the source voltage VDD (or the pull-up voltage in the case where the N-channel open-drain transistor is used in the output stage). Incidentally, the difference between the release voltage +V_{DET} and the detection voltage −V_{DET} constitutes the hysteresis band. In (b) of FIG. 6, the delay time is defined as the time from the ending point of the operating condition S4 or the starting point of the operating condition S5 to point B.

As such, based on configuration of a circuit, a predetermined level may be set such that a notification of a power status of the second device is provided to the first device based on what the first device considers is a low level.

The reset circuit 71 can be formed of Semiconductor Series R3112Q of Ricoh Company Ltd, for example. In the case where the detection voltage −V_{DET} is 2.3 V, for example, the transistor R3112Q231A-TR-F of Ricoh can be used.

Incidentally, the configuration of the reset circuit 71 is of course not limited to that of FIG. 5.

The embodiment described using FIG. 5 avoids the inconvenience and problem resulting when the low-level potential of the power ready signal PRDY_B_A output from the reset circuit 71 fails to drop sufficiently due to the sneak current. Also, the sneak current is suppressed by the reset circuit 71 having a comparatively simple circuit configuration, and therefore, the increase in the mounting area required due to the provision of the reset circuit 71 can be prevented, with the result that the steady current in the board 52 is not increased. Thus, the power status of the board 52 can be notified to the board 51 both positively and accurately.

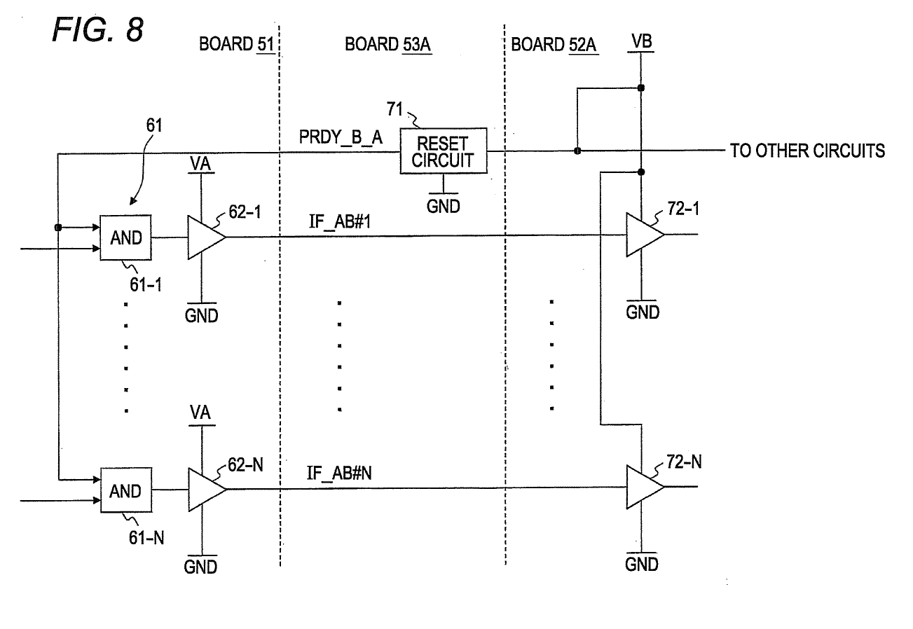

FIG. 8 is a circuit diagram showing an embodiment as an example of embodying the invention. In FIG. 8, the same component parts as those in FIG. 4 are designated by the same reference numerals, respectively, and not described again. In FIG. 8, a board 53A is arranged in place of the interface 53 (FIG. 4, and the reset circuit 71 is mounted on the board 53A but not on a board 52A.

According to this embodiment, the inconvenience and problem resulting when the low-level potential of the power ready signal PRDY_B_A output from the reset circuit 71 fails to drop sufficiently due to the sneak current is avoided. Also, the sneak current is suppressed by the reset circuit 71 having a comparatively simple circuit configuration, and therefore, the increase in the mounting area required due to the provision of the reset circuit 71 can be prevented, with the result that the steady current in the board 52 is not increased. Thus, notification of the power status of the board 52 can be provided to the board 51 both positively and accurately. Also, the reset circuit 71 is supplied with the source voltage from the board 52A, and therefore, the board 53A with the reset circuit 71 mounted thereon requires no power supply. Further, since the reset circuit 71 is not required to be mounted on the board 52A, the power consumption is reduced as compared with the embodiment described above according to which the reset circuit 71 is mounted on the board 52. Thus, the mounting area on the board 52A is not fully occupied by the reset circuit 71.

In each of the embodiments described above, the boards 51, 52, 52A are separate from each other and sometimes called units or modules with a circuit such as LSI mounted thereon. The boards 53, 53A may each be a device sometimes called a connector or an adaptor, not required to be provided with a power supply.

This invention has been described above with reference to a few embodiments. This invention, however, is not limited to those embodiments and can of course be variously modified or improved without departing from the spirit and principles of the invention, the scope of which is defined in the claims and their equivalents.

What is claimed is:

1. A power status notification method of notifying a first device having a first power supply that a second power supply of a second device is turned off, where a source voltage of the first power supply differs from a source voltage of the second power supply, comprising:
supplying the first device with a low-level notification signal indicating a power off state of the second power supply in a case where the source voltage of the second power supply drops to a predetermined voltage or is less than the predetermined voltage; and
setting the predetermined voltage at a value higher than a threshold level at which a circuit of the first device supplied with the notification signal recognizes as a low level.

2. The power status notification method according to claim 1, wherein the low-level notification signal is supplied from the second device to the first device.

3. The power status notification method according to claim 1, wherein the low-level notification signal is supplied from a third device to the first device and the third device connects the first device with the second device.

4. The power status notification method according to claim 1, wherein a high-level drive signal output from the circuit mounted on the first device to the circuit mounted on the second device is suppressed based on the low-level notification signal.

5. The power status notification method according to claim 1, wherein the low-level notification signal is output from a reset circuit which detects a decrease of the second source voltage to the predetermined voltage or less.

6. A power status notification circuit for notifying a first device having a first power supply that a second power supply of a second device is turned off, where a source voltage of the first power supply differs from a source voltage of the second power supply, comprising: a reset circuit which supplies the first device with a low-level notification signal indicating that the second power supply is turned off in a case where the source voltage of the second power supply drops to a predetermined voltage or is less than the predetermined voltage; and
a control circuit controls an input of the first device based on the low-level notification signal.

7. The power status notification circuit according to claim 6, wherein the predetermined voltage is set at a value higher than a threshold level at which the first device supplied with the notification signal recognizes a low level.

8. The power status notification circuit according to claim 6, wherein the reset circuit is mounted on the second device.

9. The power status notification circuit according to claim 6, wherein the reset circuit is mounted on a third device connecting the first device with the second device.

10. The power status notification circuit according to claim 8, wherein a high-level drive signal output from a circuit mounted on the first device to a circuit mounted on the second device is suppressed in response to the low-level notification signal.

11. A power status notification method, comprising:
setting a level for notifying a first device regarding a power status of a second device being supplied by a different source than the first device; and
notifying the first device when the power of the second device reaches the level which is determined based on a configuration of the first device.
